(19) United States
(12) Patent Application Publication
(10) Pub. No.: US 2025/0221133 A1
(43) Pub. Date: Jul. 3, 2025

(54) HIGH-REFLECTIVITY ANISOTROPIC CONDUCTIVE FILM AND DISPLAY MODULE COMPRISING THE SAME

(71) Applicant: SAMSUNG ELECTRONICS CO., LTD., Suwon-si (KR)

(72) Inventors: Shunsuke KIMURA, Suwon-si (KR); Sungjun KOH, Suwon-si (KR); Sungtae KIM, Suwon-si (KR); Heebum ROH, Suwon-si (KR); Sanghyun SOHN, Suwon-si (KR)

(73) Assignee: SAMSUNG ELECTRONICS CO., LTD., Suwon-si (KR)

(21) Appl. No.: 19/080,418

(22) Filed: Mar. 14, 2025

Related U.S. Application Data
(63) Continuation of application No. PCT/KR2023/010417, filed on Jul. 19, 2023.

(30) Foreign Application Priority Data
Sep. 16, 2022 (KR) 10-2022-0117440

(51) Int. Cl. H10H 29/80; H10H 29/85; H10H 29/851; H10H 29/855

(52) U.S. Cl. CPC H10H 29/8325; H10H 29/8512; H10H 29/8517; H10H 29/8552

(57) ABSTRACT

A display module includes a substrate; an anisotropic conductive film on one side of the substrate; a plurality of light-emitting diodes connected to the substrate via the anisotropic conductive film; and a color conversion layer on the plurality of light-emitting diodes and configured to be excited by a light having a first wavelength emitted from the plurality of light-emitting diodes and emit a light of a second wavelength that is different from the first wavelength. The anisotropic conductive film includes: an insulating adhesive layer adhering to the one side of the substrate; a plurality of conductors within the insulating adhesive layer and configured to electrically connect the plurality of light-emitting diodes to the substrate; and a plurality of reflectors within the insulating adhesive layer and having a size less than a size of the plurality of conductors.

### CROSS-REFERENCE TO RELATED APPLICATIONS

This application is a continuation of International Application No. PCT/KR2023/010417, filed on Jul. 19, 2023, which is based on and claims priority to Korean Patent Application No. 10-2022-0117440, filed on Sep. 16, 2022, in the Korean Intellectual Property Office, the disclosures of which are incorporated by reference herein in their entireties.

### BACKGROUND

### 1. Field

The present disclosure relates to a high-reflectivity anisotropic conductive film and a display module comprising the same.

### 2. Description of Related Art

An anisotropic conductive film includes a black or transparent resin film and conductive particles included in the resin film. A light-emitting diode (“LED”) or a micro LED can be connected to a substrate through the anisotropic conductive film.

When a micro LED with a size of a few tens of micrometers is connected to a substrate using an anisotropic conductive film, the side of the micro LED is inserted into the resin film. In this case, the light emitted from the side of the micro LED is mostly light absorbed by the black resin film or conductive particles. As a result, the light emitted from the side of the micro LEDs is not extracted in the vertical direction of the substrate, resulting in light loss in the display.

### SUMMARY

According to an aspect of the present disclosure, a display module includes a substrate; an anisotropic conductive film on one side of the substrate; a plurality of light-emitting diodes connected to the substrate via the anisotropic conductive film; and a color conversion layer on the plurality of light-emitting diodes and configured to be excited by a light having a first wavelength emitted from the plurality of light-emitting diodes and emit a light of a second wavelength that is different from the first wavelength. The anisotropic conductive film includes: an insulating adhesive layer adhered to the one side of the substrate; a plurality of conductors within the insulating adhesive layer and configured to electrically connect the plurality of light-emitting diodes to the substrate; and a plurality of reflectors within the insulating adhesive layer and having a size less than a size of the plurality of conductors. The anisotropic conductive film may have a reflectivity in a range of 10% to 70% based on a concentration of the plurality of reflectors.

Each of the plurality of reflectors may include at least one of TiO₂, CeO₂, ZnO, MgO, Al₂O₃, or Fe₂O₃.

Each of the plurality of reflectors may include: a polymer particle; and a conductive film coated on a surface of the polymer particle and including at least one of Ni, Fe, Co, Cu, Ag, Au, or Pt.

The insulating adhesive layer may include at least one of C, H, or O.

The display module may further include: a transparent adhesive layer covering the plurality of light-emitting diodes; a partition having a matrix shape and surrounding the color conversion layer; a black matrix on an upper end of the partition; and a color filter on the color conversion layer.

The partition may include a coating layer configured to reflect light emitted from the color conversion layer.

The color conversion layer may include an inorganic material including a quantum dot.

The color conversion layer may include any one of InP, CdSe, ZnSe, ZnTe, ZnS, and AgInS₂.

The color conversion layer may include at least one of a red quantum dot configured to emit light of a red wavelength or a green quantum dot configured to emit light of a green wavelength.

Each of the plurality of conductors may include: a body; and a conductive film coated on a surface of the body. The body may include at least one of TiO₂, CeO₂, ZnO, MgO, Al₂O₃, or Fe₂O₃.

According to an aspect of the present disclosure, a display module includes: a substrate; an anisotropic conductive film on one side of the substrate; a plurality of light-emitting diodes connected to the substrate via the anisotropic conductive film; and a color conversion layer on the plurality of light-emitting diodes and configured to be excited by a light having a first wavelength emitted from the plurality of light-emitting diodes and emit a light of a second wavelength that is different from the first wavelength. The anisotropic conductive film includes: an insulating adhesive layer adhered to the one side of the substrate; a plurality of conductors within the insulating adhesive layer and configured to electrically connect the plurality of light-emitting diodes to the substrate; and a plurality of reflectors within the insulating adhesive layer and on one side of the substrate.

Each of the plurality of reflectors may include: a photo solder resist (PSR) layer; and a metal layer coated on the PSR layer and configured to reflect light emitted from the plurality of light-emitting diodes and the color conversion layer.

The display module may further include: a transparent adhesive layer covering the plurality of light-emitting diodes; a partition having a matrix shape and surrounding the color conversion layer; a black matrix on an upper end of the partition; and a color filter on the color conversion layer.

According to an aspect of the present disclosure, an anisotropic conductive film includes: an insulating adhesive layer; a plurality of conductors within the insulating adhesive layer; and a plurality of reflectors within the insulating adhesive layer and having a size less than a size of the plurality of conductors, and each of the plurality of reflectors includes at least one of TiO₂, CeO₂, ZnO, MgO, Al₂O₃, or Fe₂O₃.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is a block diagram illustrating a display device according to one or more embodiments;

FIG. 2 is a top view illustrating a display module according to one or more embodiments;

FIG. 3 is a cross-sectional view illustrating a pixel structure of a display module according to one or more embodiments;

FIG. 4 is a cross-sectional view illustrating a portion of a pixel structure of a display module according to one or more embodiments;

FIG. 5 is a cross-sectional view illustrating a portion of a pixel structure of a display module according to one or more embodiments;

FIG. 6 is a cross-sectional view illustrating a portion of a pixel structure of a display module according to one or more embodiments; and

FIG. 7 is a cross-sectional view illustrating a conductor included in an anisotropic conductive film according to one or more embodiments.

### DETAILED DESCRIPTION

Hereinafter, various embodiments will be described in greater detail with reference to the accompanying drawings. The embodiments of the present disclosure may be modified in various ways. Specific embodiments may be illustrated in the drawings and described in detail in the detailed description. However, the specific embodiments disclosed in the accompanying drawings are only intended to facilitate understanding of the various embodiments. Therefore, the technical idea is not limited by the specific embodiments disclosed in the accompanying drawings, and the various embodiments should be understood to include all equivalents or substitutes included in the spirit and technical scope of the present disclosure.

In the disclosure, terms including ordinal numbers such as “first”, “second”, or the like may be used to described various components, but such components are not limited by the above-described terms. The above-described terms are used only to distinguish one component from another.

In the disclosure, terms such as “have”, “include”, or the like are intended to specify the presence of features, numbers, steps, operations, components, parts, or a combination thereof described in the specification, not to preclude the possibility of the presence or addition of one or more other features, numbers, steps, operations, components, parts, or a combination thereof. When a component is referred to as being “connected” or “coupled” to another component, it should be understood that it may be directly connected or coupled to another component, or that they may be connected to or coupled to each other through an intervening element. On the other hand, when a component is referred to as being “directly connected” or “directly coupled” to another component, it should be understood that there is no intervening element in-between.

In this disclosure, the term ‘same’ means not only a complete match, but also a difference that takes into account the range of processing errors.

In the disclosure, the terms “at least one of A or B”, “at least one of A and B”, “and any of A and B” includes each and every combination of A and B. For example, “at least one of A or B”, “at least one of A and B”, “any of A and B” includes only A, only B, or both A and B.

Further, in describing the disclosure, when it is decided that a detailed description for the known functions or configurations related to the disclosure may unnecessarily obscure the gist of the disclosure, the detailed description therefor will be abbreviated or omitted.

According to one or more embodiments, a display module may include a substrate, and a plurality of light-emitting diodes for displaying an image arranged on the substrate.

According to one or more embodiments, the light-emitting diodes included in the display module may be inorganic light-emitting diodes having a size of 100 micrometers or less. For example, the inorganic light-emitting diodes may be, but are not limited to, micro LEDs or mini LEDs. The inorganic light-emitting diodes have higher brightness, more luminous efficiency, and longer lifespan than organic light-emitting diodes (hereinafter, referred to as ‘OLEDs’). The inorganic light-emitting diodes may be a semiconductor chip that can emit light on their own when powered. The inorganic light-emitting diodes have a fast response time, low power, and high brightness. When the inorganic light-emitting diode is a micro LED, it may be more efficient at converting electricity into photons compared to a liquid crystal display (LCD) or OLED. For example, micro LEDs may have a higher “brightness per watt” than LCD or OLED displays. Accordingly, micro LEDs may produce the same brightness with about half the energy compared to LEDs or OLEDs exceeding 100 micrometers. The micro LEDs are capable of implementing high resolution, superior color, contrast, and brightness, making it possible to accurately represent a wide range of colors and provide a clearer screen outdoors where brightness is higher than indoors. The micro LEDs are resistant to burn-in and generate less heat, ensuring a long lifespan without deformation.

According to one or more embodiments, the light-emitting diode may be provided in the form of a flip chip in which anode and cathode electrodes are disposed on opposite sides of the light-emitting surface.

According to one or more embodiments, the substrate may have a thin film transistor (TFT) layer having a TFT circuit formed on a first surface (e.g., a front surface of the substrate). The substrate may have a power supply circuit that provides power to the TFT circuit, a data drive driver, a gate drive driver, and a timing controller that controls each drive driver on a second surface (e.g., a rear surface of the substrate). The substrate may have a plurality of pixels arranged on the TFT layer. Each pixel may be driven by the TFT circuit.

According to one or more embodiments, the TFT formed on the TFT layer may be a low-temperature polycrystalline silicon (LTPS) TFT, a low-temperature polycrystalline oxide (LTPO) TFT, or an oxide TFT.

According to one or more embodiments, the substrate on which the TFT layer is provided may be a glass substrate, a substrate of a flexible synthetic resin family (e.g., PI (polyimide), PET (polyethylene terephthalate), PES (polyethersulfone), PEN (polyethylene naphthalate), PC (polycarbonate), or a ceramic substrate.

According to one or more embodiments, the TFT layer of the substrate may be integrally formed with the first side of the substrate, or may be manufactured as a separate film and attached to the first side of the substrate.

According to one or more embodiments, the first side of the substrate may be divided into an active area and an inactive area. The active area may be an area occupied by the TFT layer in the entire area of the first side of the substrate. The inactive area may be an area excluding the active area in the entire area of the first side of the substrate.

According to one or more embodiments, an edge area of the substrate may be an outermost area of the substrate. For example, the edge area of the substrate may include an area corresponding to a side of the substrate, a portion of the first side of the substrate adjacent to each side, and a portion of the second side of the substrate. A plurality of side wirings may be disposed in the edge area of the substrate, which electrically connect a TFT circuit on the first side of the substrate and a driving circuit on the second side of the substrate.

According to one or more embodiments, the substrate may be formed in a quadrangle type. For example, the substrate may be formed as a rectangle or a square.

According to one or more embodiments, the TFT provided on the substrate may be implemented as, for example, an oxide TFT, a Si TFT (poly silicon, a-silicon), an organic TFT, a graphene TFT, etc., in addition to an LTPS TFT (low-temperature polycrystalline silicon TFT). The TFT may also be applied by making only a P-type (or N-type) MOSFET in a Si wafer CMOS process.

According to one or more embodiments, the substrate may omit the TFT layer on which the TFT circuit is formed. In this case, a plurality of micro IC chips functioning as a TFT circuit may be mounted on the first side of the substrate. In this case, the plurality of micro ICs may be electrically connected to a plurality of light-emitting diodes arranged on the first side of the substrate via wiring.

According to one or more embodiments, the pixel driving method of the display module may be an active matrix (AM) driving method or a passive matrix (PM) driving method.

According to one or more embodiments, the display module may be installed and applied in wearable devices, portable devices, handheld devices, and various electronic products or electronic devices requiring a display.

According to one or more embodiments, a plurality of display modules may be connected in a grid arrangement to form a display device such as a monitor for a personal computer, a high-resolution television and signage (or digital signage), an electronic display, and the like.

According to one or more embodiments, one pixel may include a plurality of light-emitting diodes. In this case, one light-emitting diode may be a sub-pixel. In the present disclosure, the terms “light-emitting diode”, “micro LED”, and “sub-pixel” may be used interchangeably.

Hereinafter, embodiments will be described in detail with reference to the accompanying drawings so that a person having ordinary skill in the art to which the present disclosure belongs can easily implement the present disclosure. However, the embodiments can be implemented in various different forms and are not limited to the examples described herein. In order to clearly describe the embodiments of the present disclosure in the drawings, parts that are not related to the description of the present disclosure are omitted, and similar components may be denoted by similar reference numerals.

Hereinafter, a display device and a light-emitting diode unit according to one or more embodiments will be described with reference to the accompanying drawings.

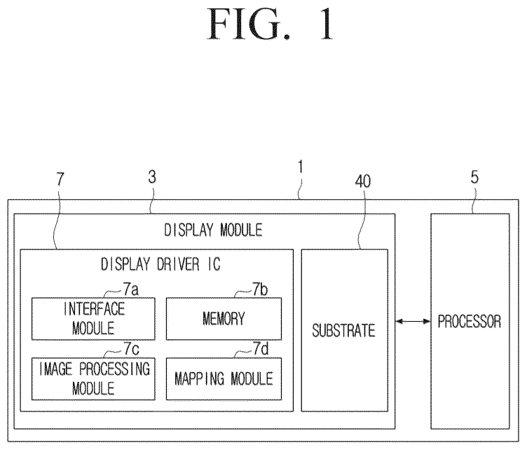

FIG. 1 is a block diagram illustrating a display device according to one or more embodiments.

Referring to FIG. 1, a display device 1 according to one or more embodiments may include a display module 3 and a processor 5.

The display module 3 may display various images. Here, the image includes a still image and/or a moving image. The display module 3 may display various images such as broadcast content, multimedia content, and the like. The display module 3 may also display a user interface and icons.

The display module 3 may include a substrate 40 and a display driver integrated circuit (DIC) 7 for controlling the substrate 40.

The display driver IC 7 may include an interface module 7a, memory 7b (e.g., buffer memory), an image processing module 7c, or a mapping module 7d. The display driver IC 7 may receive, for example, image data or image information including an image control signal corresponding to a command for controlling the image data, from another component of the display device 1 through the interface module 7a. For example, the image information may be received from the processor 5 (e.g., a main processor (e.g., an application processor) or an auxiliary processor (e.g., a graphics processing unit) that operates independently of the function of the main processor

The display driver IC 7 may store at least some of the received image information in the memory 7b, for example, on a frame basis. The image processing module 7c may, for example, perform pre-processing or post-processing (e.g., adjustment of resolution, brightness, or size) of at least some of the image data based on characteristics of the image data or characteristics of the substrate 40. The mapping module 7d may generate a voltage value or a current value corresponding to the pre-or post-processed image data via the image processing module 7c. According to an embodiment, the generation of the voltage value or current value may be based at least in part on, for example, properties of the pixels arranged on the substrate 40 (e.g., RGB stripe structure or RGB pentile structure) or the size of each of the subpixels. At least some of the pixels of the substrate 40 may be driven, for example, based at least in part on the voltage value or current value such that visual information (e.g., text, images, or icons) corresponding to the image data may be displayed via the substrate 40.

The display driver IC 7 may transmit a drive signal (e.g., a driver drive signal, a gate drive signal, etc.) to the display based on the image information received from the processor 5.

The display driver IC 7 may display an image based on the image signal received from the processor 5. In one example, the display driver IC 7 may display the image by generating a drive signal of a plurality of sub-pixels based on the image signal received from the processor 5, and controlling the light emission of the plurality of sub-pixels based on the drive signal.

The display module 3 may further include a touch circuit. The touch circuit may include a touch sensor and a touch sensor IC for controlling the touch sensor. The touch sensor IC, for example, may control the touch sensor to detect a touch input or a hovering input for a designated location on the substrate 40. For example, the touch sensor IC may detect a touch input or a hovering input by measuring a change in a signal (e.g., voltage, light, resistance, or charge) for a designated location on the substrate 40. The touch sensor IC may provide information (e.g., location, area, pressure, or time) regarding the detected touch input or hovering input to the processor 5. In one example, at least a portion of the touch circuit (e.g., the touch sensor IC) may be included as part of the display driver IC 7, as part of the substrate 40, or as part of another component (e.g., a coprocessor) disposed externally to the display module 3.

The processor 5 may be implemented as a digital signal processor (DSP) for processing a digital image signal, a microprocessor, a graphics processing unit (GPU), an artificial intelligence (AI) processor, a neural processing unit (NPU), or a time controller (TCON). However, the processor 5 is not limited thereto, and may include one or more of a central processing unit (CPU), a micro controller unit (MCU), a micro processing unit (MPU), a controller, an application processor (AP), a communication processor (CP), or an ARM processor, or may be defined by the corresponding terms. In addition, the processor 5 may be implemented as a system on chip (SoC), a large scale integration (LSI) with a built-in processing algorithm, or may be implemented in the form of an application specific integrated circuit (ASIC) or a field programmable gate array (FPGA).

The processor 5 may run an operating system or an application program to control hardware or software components connected to the processor 5, and may perform various data processing and computations. The processor 5 may also load instructions or data received from at least one of the other components into volatile memory for processing, and may store various data in non-volatile memory.

The display module 3 may be a touch screen coupled with a touch sensor, a flexible display, a rollable display, and/or a three-dimensional display.

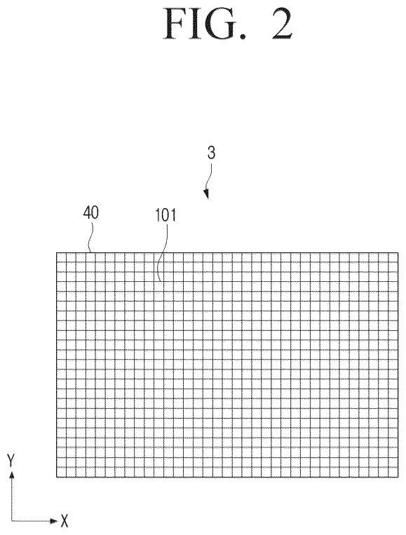

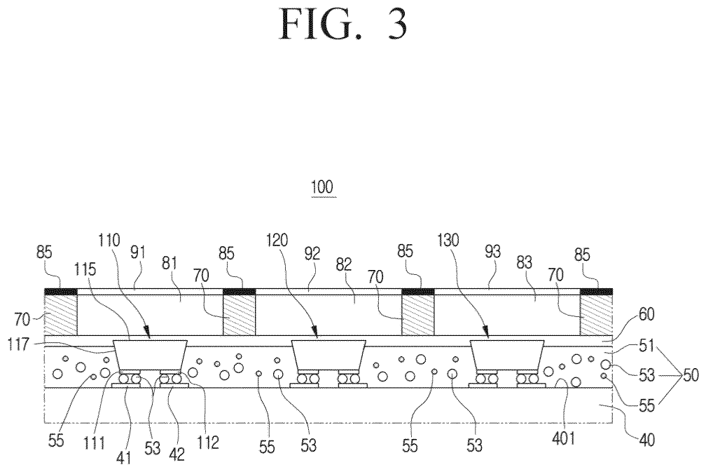

FIG. 2 is a top view illustrating a display module according to one or more embodiments. FIG. 3 is a cross-sectional view illustrating a pixel structure of a display module according to one or more embodiments.

Referring to FIGS. 2 and 3, the display module 3 may include the substrate 40 and the substrate 40 including a plurality of pixels arranged on a first side of the substrate 40. For example, the plurality of pixels may each be disposed in a pixel area 101 arranged in a matrix on the substrate 40.

The substrate 40 may be provided with a thin film transistor (TFT) circuit electrically connected to the plurality of pixels on the first side. The TFTs provided on the substrate 40 may be a-Si (amorphous silicon) TFT, LTPS (low temperature polycrystalline silicon) TFT, LTPO (low temperature polycrystalline oxide) TFT, HOP (hybrid oxide and polycrystalline silicon) TFT, LCP (liquid crystalline polymer) TFT, or OTFT (organic TFT).

On one side 401 of the substrate 40, a plurality of electrode pads 41, 42 may be arranged in pairs spaced apart from each other. The plurality of electrode pads 41, 42 may be electrically connected to first electrode 111 and second electrode 112 of a first micro LED 110, respectively. The electrodes of second and third micro LEDs 120 and 130 may also be electrically connected to the electrode pads of the corresponding substrate 40, respectively.

On one side 401 of the substrate 40, an anisotropic conductive film 50 may be laminated. The anisotropic conductive film 50 may include an insulating adhesive layer 51, a plurality of conductors 53 included in the insulating adhesive layer 51, and a plurality of reflectors 55 included in the insulating adhesive layer 51 together with the plurality of conductors 53.

The insulating adhesive layer 51 may consist of a transparent film. The insulating adhesive layer 51 may include, for example, at least one of elements C, H, or O. Alternatively, the insulating adhesive layer 51 may be a resin made of a thermosetting material (e.g., epoxy resin, polyurethane, or acrylic resin). Alternatively, the insulating adhesive layer 51 may be a non-conductive film (NCF) or a non-conductive paste (NCP).

The plurality of conductors 53 may be may be formed in a roughly ball shape with a fine size (e.g., about 3 to 15 μm). The plurality of conductors 53 may include polymer particles and a metal conductive film coated at a predetermined thickness on the outer surface of the polymer particles. The polymer particles may be elastic. The metal conductive film may include at least one of elements Ni, Fe, Co, Cu, Ag, Au, or Pt, for example.

The plurality of reflectors 55 may have a smaller size than the plurality of conductors 53, and may be formed in a roughly ball shape or bead shape. The plurality of reflectors 55 may be made of a material that is highly reflective and insulating. The plurality of reflectors 55 may include at least one of compounds of, for example, TiO₂, CeO₂, ZnO, MgO, Al₂O₃, or Fe₂O₃.

The anisotropic conductive film 50 may include a plurality of reflectors 55 to increase the reflectivity. The anisotropic conductive film 50 may have a reflectivity in the range of 10% to 70% (including both endpoints 10% and 70%) based on the concentration of the plurality of reflectors 55 (the amount of the plurality of reflectors 55 included in the anisotropic conductive film). When the reflectivity of the anisotropic conductive film 50 is less than 10%, it is difficult to expect an improvement in the light concentration using the side light of the first, second, and third micro LEDs 110, 120, and 130. When the reflectivity of the anisotropic conductive film 50 exceeds 70%, there is a problem of reduced conductivity is reduced due to a large amount of reflectors.

The display module 3 including the anisotropic conductive film 50 may reduce the proportion of light absorbed by the plurality of conductors 53 as the side light of the first, second, and third micro LEDs 110, 120, and 130 emitted in the plane direction is reflected by the plurality of reflectors 55, and may increase the amount of light emission in the vertical direction of the plane direction by reducing the light loss in the plane direction to improve the light concentration. Furthermore, red light or green light emitted from the color conversion layer described later to the lower side (to the side of the anisotropic conductive film 50) may be reflected by the plurality of reflectors 55 and re-emitted to the color conversion layer, thereby obtaining a recycling effect. Accordingly, the display module 3 may have improved light efficiency by the plurality of reflectors 55 included in the anisotropic conductive film 50.

When the plurality of conductors 53 in the anisotropic conductive film 50 are not properly distributed, the conductivity in the plane direction (the direction approximately parallel to one side 401 of the substrate 40) may occur, which may cause a short circuit between adjacent electrode pads or between electrodes of adjacent micro LEDs. According to one or more embodiments, the plurality of reflectors 55 mixed in the insulating adhesive layer 51 together with the plurality of conductors 53 have a size smaller than the size of the plurality of conductors 53, so that the conductivity in the plane direction can be prevented by appropriately controlling the concentration and dispersion of the plurality of conductors 53 in the anisotropic conductive film 50.

A pixel structure 100 may include a single pixel. One pixel may include at least three sub-pixels. The sub-pixels may be, for example, micro LEDs, which are inorganic light-emitting diodes. Hereinafter, for convenience of explanation, the sub-pixels are referred to as micro LEDs. Here, a micro LED may be an LED having a size of tens of μm or less. The three sub-pixels may be the first micro LED 110, the second micro LED 120, and the third micro LED 130. The first, second, and third micro LEDs 110, 120, and 130 may emit light in a blue wavelength band.

In each pixel area 101, the first micro LED 110, the second micro LED 120, and the third micro LED 130 may be disposed. In an area of the pixel area, which is not occupied by the first, second, and third micro LEDs 110, 120, and 130, a plurality of TFTs for driving the first, second, and third micro LEDs 110, 120, and 130 may be disposed.

The first, second, and third micro LEDs 110, 120, and 130 may be arranged in a row at regular intervals, but are not limited thereto. For example, the first, second, and third micro LEDs 110, 120, and 130 may be arranged in an L-shape or in a pentile RGBG scheme. The pentile RGBG scheme is a scheme in which the number of red, green, and blue sub-pixels is arranged in a ratio of 1:1:2 (RGBG) by utilizing the cognitive characteristic of humans identifying green better than blue. The pentile RGBG scheme may increase yield and reduce unit cost. The pentile RGBG scheme may implement high resolution on a small screen.

A pixel is described as including three micro LEDs 110, 120, and 130, but is not limited thereto. For example, a pixel may include one micro LED or may include four or more micro LEDs (e.g., red, green, blue, white LEDs).

The first, second, and third micro LEDs 110, 120, and 130 may be transferred to the substrate 40 via any of a laser transfer method, a self-assembly method, a roll transfer method, an electrostatic MEMS (microelectromechanical system) method, a vacuum membrane method, and an elastomeric stamp method.

The first, second, and third micro LEDs 110, 120, and 130 transferred to the substrate 40 may be mounted on the substrate 40 via a thermal compression process. In this case, the first, second, and third micro LEDs 110, 120, and 130 may be connected to the substrate 40 through the anisotropic conductive film 50 attached to the one side 401 of the substrate 40. The first, second, and third micro LEDs 110, 120, and 130 may be pressed toward the substrate 40 during thermal compression so that the side surfaces of the first, second, and third micro LEDs 110, 120, and 130 may be inserted into the anisotropic conductive film 50. Accordingly, the side light emitted from the side of the first, second, and third micro LEDs 110, 120, and 130 may be reflected by the plurality of reflectors 55 included in the anisotropic conductive film 50 and emitted in a direction perpendicular to the plane direction.

Further, by the thermal compression process, the first and second electrodes 111, 112 of the first micro LED 110 may be electrically and physically connected to the pair of electrode pads 41, 42 of the substrate 40 by the plurality of conductors 53. For example, the plurality of conductors 53 may be eutectic bonded to the first and second electrodes 111, 112 of the first micro LED 110 and the pair of electrode pads 41, 42, respectively, by the high temperature heat provided during the thermal compression process. The second and third micro LEDs 120 and 130, like the first micro LED 110, may have the first and second electrodes of the second and third micro LEDs 120 and 130 electrically and physically connected to the corresponding electrode pads, respectively, by the plurality of conductors 53.

The pixel structure 100 may include a transparent adhesive layer 60 covering the upper portion of the first, second, and third micro LEDs 110, 120, and 130 to allow a partition 70, a first color conversion layer 81, a second color conversion layer 82, and a first transparent resin layer 83 to be attached to the substrate 40. The transparent adhesive layer 60 may be an optical clear adhesive (OCA) having excellent workability and a uniform surface.

The pixel structure 100 may include the partition 70, the first color conversion layer 81, the second color conversion layer 82, and the first transparent resin layer 83. The partition 70, the first color conversion layer 81, the second color conversion layer 82, and the first transparent resin layer 83 may be located in the same layer.

The light-emitting areas of the first, second, and third micro LEDs 61, 62, 63 may be partitioned by the partition 70. The partition 70 may be formed in a roughly grid shape. The plurality of light-emitting areas partitioned by the partition 70 may each correspond to one sub-pixel area.

The partition 70 may have a white color with excellent light reflectivity to function as a reflector. Here, the white color may include true white and off-white. The off-white may be any color close to white.

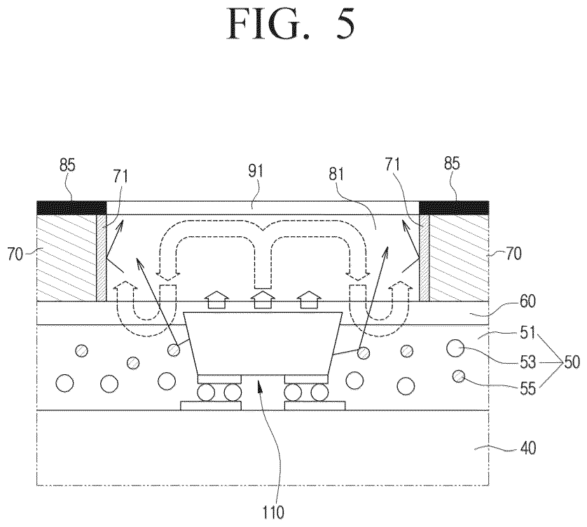

The partition 70 may be formed of a highly reflective metal material to function as a reflector. Alternatively, the partition 70 may be laminated with a highly reflective metal film 74 on the sides as shown in FIG. 5. In this case, the partition 70 does not have to have a white color. The partition 70 may reflect light emitted from the sides of the first and second color conversion layers 81, 82 and light emitted from the sides of the third micro LED 130 to improve light efficiency by emitting the light in a direction perpendicular to the plane direction.

In each light-emitting area partitioned by the partition 70, the first and second color conversion layers 81, 82 and the first transparent resin layer 83 may be disposed.

The first and second color conversion layers 81, 82 may be made of a material including quantum dots that convert and emit light emitted from the first and second micro LEDs 110, 120 into light of different wavelength bands. The inorganic material constituting the quantum dots may include any one of InP, CdSe, ZnSe, ZnTe, ZnS, and AgInS₂.

The first color conversion layer 81 may be made of a material including red quantum dots that may be excited by light in the blue wavelength band emitted from the first micro LED 110 to emit light in the red wavelength band.

The second color conversion layer 82 may be made of a material including green quantum dots that may be excited by light in the blue wavelength band emitted from the second micro LED 120 to emit light in the green wavelength band.

The first and second color conversion layers 81, 82 are not limited to materials including quantum dots, and may be nanophosphors. The nanophosphors exhibit different physical properties compared to phosphors having particle diameters of several μm. Since the gap between the energy bands, which is the quantum state energy level structure of electrons in the crystal of the nanophosphors, is large, the wavelength of the emitted light has high energy, so that the light-emitting efficiency can be improved. Since the particle density of the nanophosphors increases compared to the phosphors having a bulk structure in the area to which the phosphors are applied, the colliding electrons effectively contribute to luminescence, so that the efficiency of the display can be improved. For example, the first color conversion layer 81 may include a red nanophosphor. The second color conversion layer 82 may include a green nanophosphor.

The first transparent resin layer 83 may be made of a material that does not affect or can minimize the transmittance, reflectivity, and refractive index of the light emitted from the third micro LED 63.

The pixel structure 100 may include a black matrix 85 corresponding to the partition 70, first and second color filters 91, 92 corresponding to the first and second color conversion layers 81, 82, respectively, and a second transparent resin layer 93 corresponding to the first transparent resin layer 83.

The black matrix 85 is disposed on the top of the partition 70, and may be formed in a matrix shape corresponding to the shape of the partition 70. In this case, the width of the black matrix 85 may be formed similar to the width of the partition 70. The black matrix 85 may partition the area in which the first and second color filters 91, 92 and the second transparent resin layer 93 are disposed.

The first color filter 91 may be a red color filter that passes a wavelength of the same color as the color of the light in the red wavelength band emitted from the first color conversion layer 81. The second color filter 92 may be a green color filter that passes a wavelength of the same color as the color of the light in the green wavelength band emitted from the second color conversion layer 82.

The second transparent resin layer 93 may be made of a material that does not affect or can minimize the transmittance, reflectivity, and refractive index of light that has passed through the first transparent resin layer 83. The second transparent resin layer 93 may be an optical film that can direct light toward the front through refraction and reflection to minimize wasted light and improve luminance.

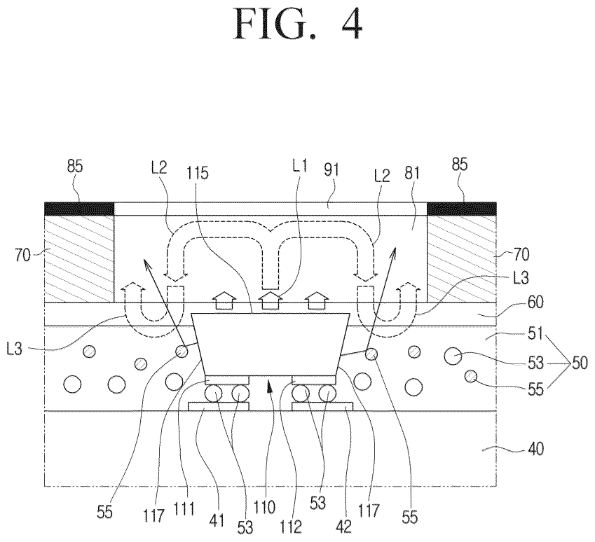

FIG. 4 is a cross-sectional view illustrating a portion of a pixel structure of a display module according to one or more embodiments. Here, the portion of the pixel structure may be an area in which the first micro LED 110 emitting light in the red wavelength band is disposed.

Referring to FIG. 4, the first micro LED 110 may be electrically connected to the substrate 40 via the anisotropic conductive film 50. The first and second electrodes 111, 112 of the first micro LED 110 and the first and second electrode pads 41, 42 of the substrate 40 may be electrically connected to each other through the plurality of conductors 53. Accordingly, the first micro LED 110 may be electrically connected to a plurality of TFTs provided on the substrate 40.

The first micro LED 110 may be turned on or off through a plurality of TFTs controlled by the processor 5 (see FIG. 1). When the first micro LED 110 is turned on, the first micro LED 110 may emit light in the blue wavelength band (hereinafter, referred to as blue light) to a light-emitting surface 115 and a side 117.

The blue light L1 emitted from the light-emitting surface 115 of the first micro LED 110 may be incident on the first color conversion layer 81. The red quantum dot (QD) included in the first color conversion layer 81 may be excited by the blue light L1 to emit light in the red wavelength band (hereinafter, referred to as red light, L2).

The red light L2 emitted from the first color conversion layer 81 may pass through the first color filter 91 and be emitted in the front direction of the display module 3. The first color filter 91 may filter wavelengths other than red wavelengths included in the red light L2.

Some of the red light L2 emitted from the first color conversion layer 81 may be emitted toward the anisotropic conductive film 50. The red light L3 emitted to the anisotropic conductive film 50 may be reflected by the plurality of reflectors 55 to the first color conversion layer 81. The red light L3 reflected by the plurality of reflectors 55 may pass through the first color conversion layer 81 and the first color filter 91 and be emitted to the front of the display module 3. Accordingly, the amount of red light L2, L3 emitted to the front of the display module 3 may increase.

In addition, the first micro LED 110 may also emit blue light from the side 117 in the plane direction. In this case, the blue light emitted from the side 117 of the first micro LED 110 may be reflected by the plurality of reflectors 55 and incident on the first color conversion layer 81. The red quantum dot included in the first color conversion layer 81 may be excited by the blue light and emit the red light L2. Accordingly, since the amount of red light emitted to the front of the display module 3 may further increase, the light loss in the plane direction may be reduced, thereby improving the light concentration.

The blue light emitted from the light-emitting surface of the second micro LED 120 may be incident on the second color conversion layer 82. The green quantum dot included in the second color conversion layer 82 may be excited by the blue light to emit light in the green wavelength band (hereinafter, referred to as green light). Most of the green light passes through the second color filter 92 and is emitted to the front of the display module 3, and a portion of the green light emitted toward the anisotropic conductive film 50 may be reflected by the plurality of reflectors 55, pass through the second color conversion layer 82 and the second color filter 92, and be emitted to the front of the display module 3. In addition, the blue light emitted in the plane direction from the side of the second micro LED 120 may be reflected by the plurality of reflectors 55 onto the second color conversion layer. In this case, the green quantum dot included in the second color conversion layer 82 may be excited by the blue light and emit green light. The green light may be emitted to the front of the display module 3 through the second color filter 92. Accordingly, the amount of green light emitted to the front of the display module 3 may increase.

The blue light emitted from the light-emitting surface of the third micro LED 130 may pass through the first transparent resin layer 83 and the second transparent resin layer 93 and be emitted to the front of the display module 3. The blue light emitted in the plane direction from the side of the third micro LED 130 may be reflected by the plurality of reflectors 55, pass through the first transparent resin layer 83 and the second transparent resin layer 93, and be emitted to the front of the display module 3. Accordingly, the amount of blue light emitted to the front of the display module 3 may increase.

FIG. 5 is a cross-sectional view illustrating a portion of a pixel structure of a display module according to one or more embodiments. The pixel structure of the display module illustrated in FIG. 5 is substantially the same as the pixel structure of the display module illustrated in FIG. 4. Accordingly, each of the configurations shown in FIG. 5 that correspond to each of the configurations shown in FIG. 4 is assigned the same reference numeral as in FIG. 4.

Referring to FIG. 5, the pixel structure of the display module may further include a coating layer 71 on the partition 70. The coating layer 71 may be a highly reflective metal.

The red quantum dot included in the first color conversion layer 81 is excited by the blue light incident on the first color conversion layer 81 and emits red light. The coating layer 71 reflects the red light emitted from the first color conversion layer 81 toward the first color filter 91. The red light reflected toward the first color filter 91 may be emitted to the front of the display module 3.

Some of the red light reflected by the coating layer 71 and emitted toward the anisotropic conductive film 50 may be re-reflected by the plurality of reflectors 55 to the first color conversion layer 81. The red light re-reflected to the first color conversion layer 81 may pass through the first color conversion layer 81 and the first color filter 91 and then, be emitted to the front of the display module 3.

The coating layer 71 may also be formed on the partition that partitions the second color conversion layer 82 and the partition 70 that partitions the first transparent resin layer 83, respectively.

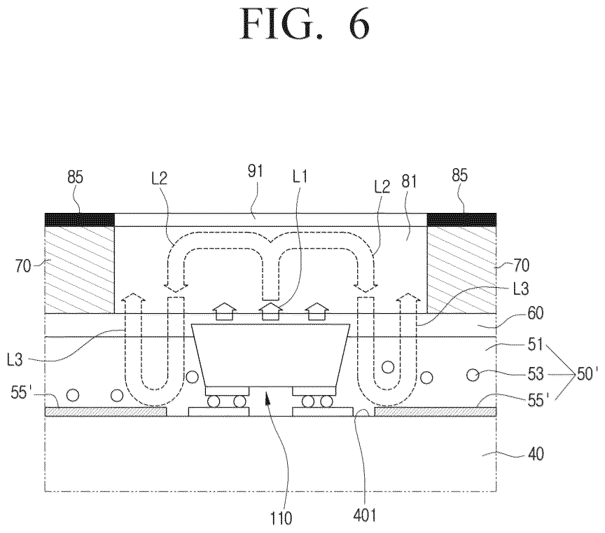

FIG. 6 is a cross-sectional view illustrating a portion of a pixel structure of a display module according to one or more embodiments. The pixel structure of the display module illustrated in FIG. 6 is substantially the same as the pixel structure of the display module illustrated in FIG. 4. Accordingly, each of the configurations shown in FIG. 6 that correspond to each of the configurations shown in FIG. 4 is assigned the same reference numeral as in FIG. 4.

Referring to FIG. 6, an anisotropic conductive film 50′ may omit the plurality of conductors 53 (see FIG. 4), and include a reflective layer 55′ that functions as a plurality of conductors 44.

The reflective layer 55′ may be formed on one side 401 of the substrate 40. The reflective layer 55′ may include a photo solder resist (PSR) layer and a thin metal layer coated on the PSR layer. The PSR layer may include at least one of elements C, H, or O. The metal layer may be a highly reflective metal material.

The reflective layer 55′ may reflect the red light emitted toward the toward the anisotropic conductive film 50′ in the red light emitted from the first color conversion layer 81 to the first color conversion layer 81. The red light reflected to the first color conversion layer 81 may pass through the first color conversion layer 81 and the first color filter 91 and be emitted to the front of the display module 3.

As such, the reflective layer 55′ is formed on one side of the substrate 40 around the first micro LED 110, so the amount of red light emitted to the front of the display module 3 through the first color conversion layer 81 and the first color filter 91 may increase.

The reflective layer 55′ may be formed on one side of the substrate 40 around the second micro LED 120. In addition, the reflective layer 55′ may be formed on one side of the substrate 40 around the third micro LED 130.

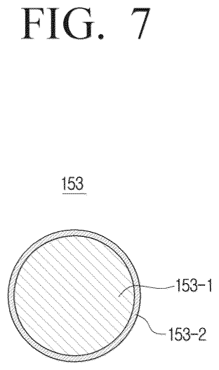

FIG. 7 is a cross-sectional view illustrating a conductor included in an anisotropic conductive film according to one or more embodiments.

Referring to FIG. 7, a plurality of conductors 153 included in the anisotropic conductive films 50, 50′ may include a body 153-1 made of a highly reflective oxide, and a conductive film 153-2 coated on a surface of the body 153-1.

The body 153-1 may include at least one of compounds of, for example, TiO₂, CeO₂, ZnO, MgO, Al₂O₃, or Fe₂O₃. The conductive film 153-2 may include at least one of elements of, for example, Ni, Fe, Co, Cu, Ag, Au, or Pt.

As the body 153-1 of the plurality of conductors 153 is made of an oxide having a high reflectivity, it can reflect the blue light emitted from the first, second, and third micro LEDs 110, 120, and 130 and the red light and green light emitted from the first and second color conversion layers 81, 82 together with the plurality of reflectors 55 or reflective layers 55′. Accordingly, the amount of red light, green light, and blue light emitted to the front of the display module 3 may increase.

While the disclosure has been illustrated and described with reference to embodiments, it will be understood that the embodiments are intended to be illustrative, not limiting. It will be further understood by those skilled in the art that various changes in form and detail may be made without departing from the true spirit and full scope of the disclosure, including the appended claims and their equivalents. It will also be understood that any of the embodiments described herein may be used in conjunction with any other embodiments described herein.

What is claimed is:

1. A display module comprising:
a substrate;
an anisotropic conductive film on one side of the substrate;
a plurality of light-emitting diodes connected to the substrate via the anisotropic conductive film; and
a color conversion layer on the plurality of light-emitting diodes and configured to be excited by light having a first wavelength emitted from the plurality of light-emitting diodes and emit light of a second wavelength that is different from the first wavelength,
wherein the anisotropic conductive film comprises:
an insulating adhesive layer adhered to the one side of the substrate;
a plurality of conductors within the insulating adhesive layer and electrically connecting the plurality of light-emitting diodes to the substrate; and
a plurality of reflectors within the insulating adhesive layer and having a size less than a size of the plurality of conductors.

2. The display module as claimed in claim 1, wherein the anisotropic conductive film has a reflectivity in a range of 10% to 70% based on a concentration of the plurality of reflectors.

3. The display module as claimed in claim 1, wherein each of the plurality of reflectors comprises at least one of TiO₂, CeO₂, ZnO, MgO, Al₂O₃, or Fe₂O₃.

4. The display module as claimed in claim 1, wherein each of the plurality of reflectors comprises:
a polymer particle; and
a conductive film coated on a surface of the polymer particle and comprising at least one of Ni, Fe, Co, Cu, Ag, Au, or Pt.

5. The display module as claimed in claim 1, wherein the insulating adhesive layer comprises at least one of C, H, or O.

6. The display module as claimed in claim 1, further comprising:
a transparent adhesive layer covering the plurality of light-emitting diodes;
a partition having a matrix shape and surrounding the color conversion layer;
a black matrix on an upper end of the partition; and
a color filter on the color conversion layer.

7. The display module as claimed in claim 6, wherein the partition comprises a coating layer configured to reflect light emitted from the color conversion layer.

8. The display module as claimed in claim 1, wherein the color conversion layer comprises an inorganic material comprising a quantum dot.

9. The display module as claimed in claim 8, wherein the color conversion layer comprises any one of InP, CdSe, ZnSe, ZnTe, ZnS, and AgInS₂.

10. The display module as claimed in claim 8, wherein the color conversion layer comprises at least one of a red quantum dot configured to emit light of a red wavelength or a green quantum dot configured to emit light of a green wavelength.

11. The display module as claimed in claim 1, wherein each of the plurality of conductors comprises:
a body; and
a conductive film coated on a surface of the body, and
wherein the body comprises at least one of TiO₂, CeO₂, ZnO, MgO, Al₂O₃, or Fe₂O₃.

12. A display module comprising:
a substrate;
an anisotropic conductive film on one side of the substrate;
a plurality of light-emitting diodes connected to the substrate via the anisotropic conductive film; and
a color conversion layer on the plurality of light-emitting diodes and configured to be excited by light having a first wavelength emitted from the plurality of light-emitting diodes and emit light of a second wavelength that is different from the first wavelength,
wherein the anisotropic conductive film comprises:
an insulating adhesive layer adhered to the one side of the substrate;
a plurality of conductors within the insulating adhesive layer and electrically connecting the plurality of light-emitting diodes to the substrate; and
a plurality of reflectors within the insulating adhesive layer and on one side of the substrate.

13. The display module as claimed in claim 12, wherein each of the plurality of reflectors comprises:
a photo solder resist (PSR) layer; and
a metal layer coated on the PSR layer and configured to reflect light emitted from the plurality of light-emitting diodes and the color conversion layer.

14. The display module as claimed in claim 12, further comprising:
a transparent adhesive layer covering the plurality of light-emitting diodes;
a partition having a matrix shape and surrounding the color conversion layer;
a black matrix on an upper end of the partition; and
a color filter on the color conversion layer.

15. An anisotropic conductive film comprising:
an insulating adhesive layer;
a plurality of conductors within the insulating adhesive layer; and
a plurality of reflectors within the insulating adhesive layer and having a size less than a size of the plurality of conductors,
wherein each of the plurality of reflectors comprises at least one of TiO₂, CeO₂, ZnO, MgO, Al₂O₃, or Fe₂O₃.
